(19) United States
(12) Patent Application Publication
(10) Pub. No.: US 2026/0367541 A1
(43) Pub. Date: Nov. 19, 2026

(54) LITHOGRAPHY SYSTEM WITH FUEL CELL AND METHODS

(71) Applicant: Taiwan Semiconductor Manufacturing Co., Ltd., Hsinchu (TW)

(72) Inventors: Chien-Hua FU, Hsinchu (TW); Che-Chang HSU, Hsinchu (TW); Kai-Fa HO, Hsinchu (TW); Li-Jui CHEN, Hsinchu (TW)

(73) Assignee: Taiwan Semiconductor Manufacturing Co., Ltd., Hsinchu (TW)

(21) Appl. No.: 19/753,593

(22) Filed: Jul. 24, 2026

Related U.S. Application Data
(63) Continuation of application No. 18/472,779, filed on Sep. 22, 2023.

(51) Int. Cl. G03F 7/00; G03F 7/20; H01M 8/04029; H01M 8/0662; H01M 8/24; H01M 10/44; H01M 16/00; H10P 76/00

(52) U.S. Cl. CPC G03F 7/70991; G03F 7/2004; G03F 7/70033; G03F 7/70925; H01M 8/04029; H01M 8/0662; H01M 8/24; H01M 10/44; H01M 16/006; H10P 76/00; H01M 2220/10; H01M 2250/10

(57) ABSTRACT

A method includes: forming a mask layer on a semiconductor wafer; generating light by a tin droplet by a lithography exposure system; exposing the mask layer by the light; cleaning tin debris accumulated in the lithography exposure system by hydrogen gas; pumping the hydrogen gas from the lithography exposure system to a fuel cell; and generating electric power by the fuel cell.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of portions of a lithography scanner according to embodiments of the present disclosure.

FIGS. 2-6 are views of various embodiments of a system including a lithography apparatus and a fuel cell according to various aspects of the present disclosure.

FIG. 7 is a flowchart of a method of fabricating a device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

The present disclosure is generally related to lithography equipment for fabricating semiconductor devices, and more particularly to a system that includes a fuel cell that converts spent hydrogen gas from a lithography apparatus into electric power and method that improves power efficiency associated with use of an extreme ultraviolet (EUV) lithography apparatus.

For several decades, lithography for producing semiconductor devices has been extended by increasing numerical aperture (NA) of projection optics of exposure tools relative to prior generations of systems operating at a same wavelength. Such an extension is in continued development for leading-edge lithographic technology, such as extreme ultraviolet (EUV) lithography. EUV lithography has established itself as the technology of choice for High-Volume Manufacturing (HVM) of a 5 nanometer (nm) node and beyond, continuing Moore’s law for the coming years. Even with outstanding imaging and overlay capability of current EUV scanners, device output and yield can still be affected adversely by other factors, such as molecular or particulate contamination on imaging surfaces. Also, it is beneficial to maintain high source power and mirror reflectivity over the full lifetime of the scanner. From this point of view, the usage of hydrogen gases is beneficial to prevent these issues due to reaction with tin plasma. A large amount of the hydrogen gases is used during the exposure and is burned in a scrubber directly. The hydrogen gases are products of fossil fuels for industrial manufacturing usage.

Embodiments of the disclosure provide a method of reusing the hydrogen gases by a fuel cell to generate electric power during operation of an EUV lithography system. Under the concept of environmental, social and corporate governance (ESG), the hydrogen gas being reused in manufacturing reduces waste, which is a company’s responsibility for global value. The fuel cell(s) are positioned between a pump and the scrubber to reuse the spent hydrogen gases to generate electric power for green manufacturing. A structure including multiple fuel cells also has the benefits of easy maintenance and repair. Use of the fuel cell(s) can reduce energy per wafer (EPW), which is a measure of cost of electricity per wafer processed by the EUV lithography system. The fuel cell(s) become increasingly beneficial with increased use of hydrogen gas, which is expected for each new fabrication node.

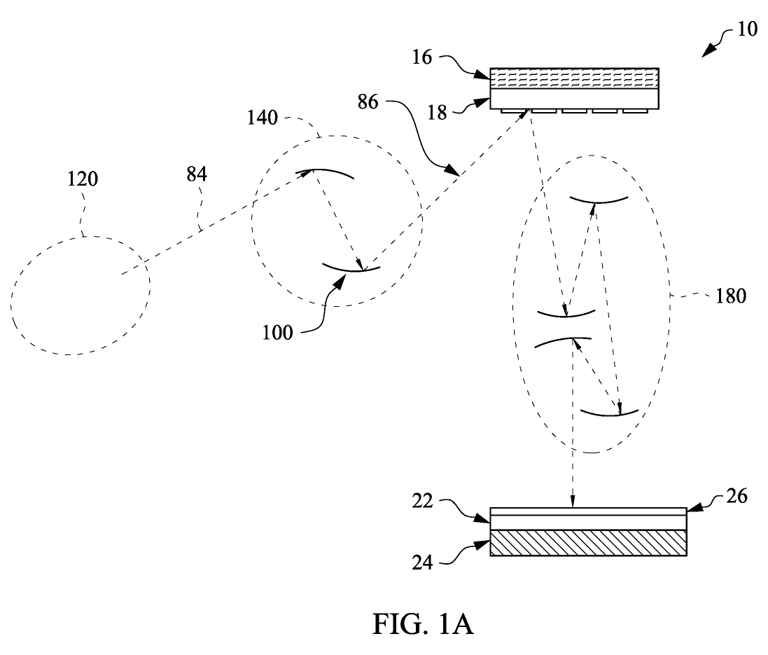

FIG. 1A is a schematic and diagrammatic view of a lithography exposure system or apparatus 10, in accordance with some embodiments. The lithography exposure system 10 is described in detail to provide context for understanding a power supply system 222 for reusing hydrogen gas that cleans a collector of the lithography exposure system 10.

In some embodiments, the lithography exposure system 10 is an extreme ultraviolet (EUV) lithography system designed to expose a resist layer by EUV radiation, and may also be referred to as the EUV system 10. The EUV system 10 may also be referred to as an EUV scanner or lithography scanner. The lithography exposure system 10 includes a light source 120, an illuminator 140, a mask stage 16, a projection optics module (or projection optics box (POB)) 180 and a substrate stage 24, in accordance with some embodiments. The elements of the lithography exposure system 10 can be added to or omitted, and the disclosure should not be limited by the embodiment.

The light source 120 is configured to generate light radiation having a wavelength ranging between about 1 nm and about 300 nm in certain embodiments. In one particular example, the light source 120 generates an EUV radiation with a wavelength centered at about or substantially 13.5 nm. Accordingly, the light source 120 is also referred to as an EUV radiation source. However, it should be appreciated that the light source 120 should not be limited to emitting EUV radiation. The light source 120 can be utilized to perform any high-intensity photon emission from excited target fuel.

In various embodiments, the illuminator 140 includes various refractive optic components, such as a single lens or a lens system having multiple reflectors 100, for example lenses (zone plates) or alternatively reflective optics (for EUV lithography exposure system), such as a single mirror or a mirror system having multiple mirrors in order to direct light from the light source 120 onto the mask stage 16, particularly to a mask 18 secured on the mask stage 16. In embodiments in which the light source 120 generates light in the EUV wavelength range, reflective optics are employed. In some embodiments, the illuminator 140 includes at least two reflectors, at least three reflectors, or more.

The mask stage 16 is configured to secure the mask 18. In some embodiments, the mask stage 16 includes an electrostatic chuck (e-chuck) to secure the mask 18. One reason an e-chuck is beneficial is that gas molecules absorb EUV radiation and the e-chuck is operable in the lithography exposure system for the EUV lithography patterning that is maintained in a vacuum environment to avoid EUV intensity loss. In the present disclosure, the terms mask, photomask, and reticle are used interchangeably. In the present embodiment, the mask 18 is a reflective mask. One example structure of the mask 18 includes a substrate with a suitable material, such as a low thermal expansion material (LTEM) or fused quartz. In various examples, the LTEM includes TiO₂ doped SiO₂, or other suitable materials with low thermal expansion. The mask 18 includes a reflective multilayer deposited on the substrate. The mask stage 16 is operable to translate in two horizontal directions, such as an X-axis direction and a Y-axis direction, so as to expose multiple different regions of the semiconductor wafer 22 to light having a pattern generated by the mask 18. The semiconductor wafer 22 may have a mask layer 26 thereon, which may be a photoresist layer that is sensitive to the light carrying the pattern of the mask 18.

The projection optics module (or projection optics box (POB)) 180 is configured for imaging the pattern of the mask 18 on to a semiconductor wafer 22 secured on the substrate stage 24 of the lithography exposure system 10. In some embodiments, the POB 180 has refractive optics (such as for a UV lithography exposure system) or alternatively reflective optics (such as for an EUV lithography exposure system) in various embodiments. The light directed from the mask 18, carrying the image of the pattern on the mask, is collected by the POB 180. The illuminator 140 and the POB 180 may be referred to collectively as an optical module of the lithography exposure system 10. In some embodiments, the POB 180 includes at least six reflective optics.

In some embodiments, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In addition, the semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), capacitors, inductors, diodes, and/or other applicable elements. Various processes are performed to form the device elements, such as deposition, etching, implantation, photolithography, annealing, and/or other suitable processes. In some embodiments, the semiconductor wafer 22 is coated with a resist layer sensitive to the EUV radiation. Various components including those described above are integrated together and are operable to perform lithography processes.

The lithography exposure system 10 may include other modules or be integrated with (or be coupled with) other modules, such as a cleaning module or apparatus or system 62 designed to provide hydrogen gas to the light source 120 and a tin supply system designed to provide liquid tin to the light source 120. The hydrogen gas helps reduce contamination in the light source 120. The cleaning system 62 may clean a collector of the light source 120, but is not limited thereto. For example, tin debris 82A may settle on a variety of components of the lithography exposure system 10, and the cleaning system 62 may expel the hydrogen gas toward the various components to remove the tin debris 82A. Further description of the light source 120 and cleaning system 62 is provided with reference to FIG. 1B.

In FIG. 1B, the light source 120 is shown in a diagrammatical view, in accordance with some embodiments. In some embodiments, the light source 120 employs a dual-pulse laser produced plasma (LPP) mechanism to generate plasma 88 and further generate EUV radiation from the plasma. The light source 120 includes a droplet generator 30, a droplet receptacle 35, a laser generator 50, a laser produced plasma (LPP) collector 60, a monitoring device 70 and a controller 90. Some or all of the above-mentioned elements of the light source 120 may be held under vacuum. It should be appreciated that the elements of the light source 120 can be added to or omitted, and should not be limited by the embodiment.

The droplet generator 30 is configured to generate a plurality of droplets 82, which may be elongated, of a target fuel 80 to a zone of excitation at which at least one laser pulse 51 from the laser generator 50 hits the droplets 82, as shown in FIG. 1B. In an embodiment, the target fuel 80 includes tin (Sn). In an embodiment, the droplets 82 may be formed with an elliptical shape. In an embodiment, the droplets 82 are generated at a rate of about 50 kilohertz (kHz) and are introduced into the zone of excitation in the light source 120 at a speed of about 70 meters per second (m/s). Other material can also be used for the target fuel 80, for example, a tin containing liquid material such as eutectic alloy containing tin, lithium (Li), and xenon (Xe). The target fuel 80 in the droplet generator 30 may be in a liquid phase.

The laser generator 50 is configured to generate at least one laser pulse to allow the conversion of the droplets 82 into plasma 88. In some embodiments, the laser generator 50 is configured to produce a laser pulse 51 to the lighting point 52 to convert the droplets 82 to plasma 88 which generates EUV radiation 84. The laser pulse 51 is directed through window (or lens) 55, and irradiates droplets 82 at the lighting point 52. The window 55 is formed in the sectional collector 60 and adopts a suitable material substantially transparent to the laser pulse 51. The droplet receptacle 35 catches and collects unused droplets 82 and/or scattered material of the droplets 82 resulting from the laser pulse 51 striking the droplets 82. Some of the scattered material may settle on various components of the lithography exposure system 10, such as a collector 60 of the light source 120, which is nearest the tin droplets 82 as they are struck by the laser pulse 51.

The plasma emits EUV radiation 84, which is collected by the collector 60. The collector 60 further reflects and focuses the EUV radiation 84 for the lithography processes performed through an exposure tool. In some embodiments, the collector 60 has an optical axis 61 which is parallel to the z-axis and perpendicular to the x-axis. The collector 60 may include a single section, as shown, or at least two sections that are offset from each other in the z-axis direction.

The collector 60 may further include a vessel wall 65 having the cleaning system 62 and first and second pumps 66, 68 attached thereto. The cleaning system 62 may include one or more nozzles that may be directed toward areas of the lithography exposure system 10, such as the collector 60, to expel hydrogen gas at high pressure to remove the debris 82A from the surface of the collector 60. The cleaning by the cleaning system 62 is highly beneficial to maintaining a mirror surface of the collector 60, which increases light output power by the light source 120 and improves wafer throughput.

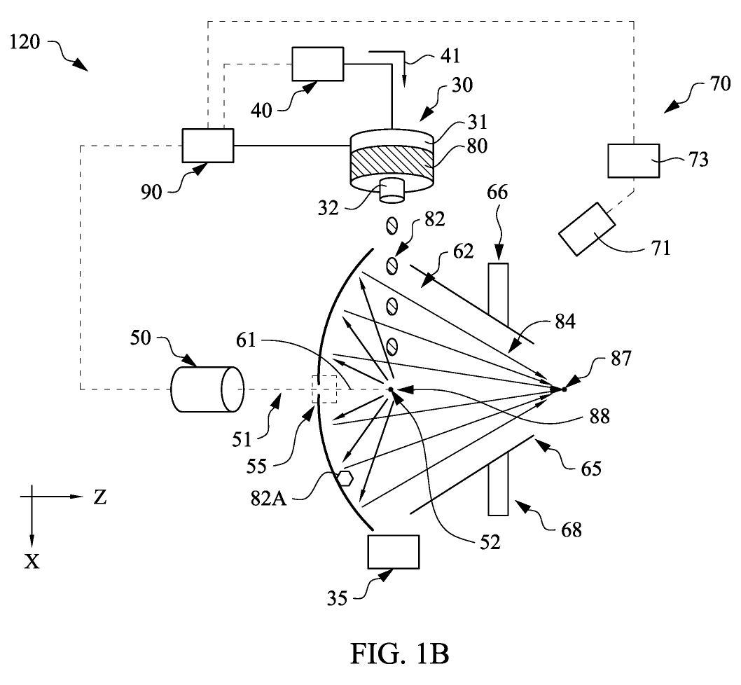

In some embodiments, the first and second pumps 66, 68 include scrubbers configured to remove particulates and/or gases from the collector 60. The first and second pumps 66, 68 may be collectively referred to as “the pumps 66, 68” herein. In some embodiments, the pumps 66, 68 do not include scrubbers and instead the scrubber(s) are external to the pumps 66, 68 and in fluidic communication with the pumps 66, 68 via one or more fuel cells, as will be described in greater detail with reference to FIG. 2. The pumps 66, 68 are operable to evacuate hydrogen gas (e.g., spent hydrogen gas) out of the lithography exposure system 10 toward the fuel cell(s).

In an embodiment, the laser generator 50 is a carbon dioxide (CO2) laser source. In some embodiments, the laser generator 50 is used to generate the laser pulse 51 with single wavelength. The laser pulse 51 is transmitted through an optic assembly for focusing and determining incident angle of the laser pulse 51. In some embodiments, the laser pulse 51 has a spot size of about 200-300 μm, such as 225 μm. The laser pulse 51 is generated to have certain driving power to meet wafer production targets, such as a throughput of 125 wafers per hour (WPH). For example, the laser pulse 51 is equipped with about 23 kW driving power. In various embodiments, the driving power of the laser pulse 51 is at least 20 kW, such as 27 kW.

The monitoring device 70 is configured to monitor one or more conditions in the light source 120 so as to produce data for controlling configurable parameters of the light source 120. In some embodiments, the monitoring device 70 includes a metrology tool 71 and an analyzer 73. In cases where the metrology tool 71 is configured to monitor condition of the droplets 82 supplied by the droplet generator 30, the metrology tool 71 may include an image sensor, such as a charge coupled device (CCD), complementary metal oxide semiconductor sensor (CMOS) sensor or the like. The metrology tool 71 produces a monitoring image including image or video of the droplets 82 and transmits the monitoring image to the analyzer 73. In cases where the metrology tool 71 is configured to detect energy or intensity of the EUV light radiation 84 produced by the droplet 82 in the light source 120, the meteorology tool 71 may include a number of energy sensors. The energy sensors may be any suitable sensors that are able to observe and measure energy of electromagnetic radiation in the ultraviolet region.

The analyzer 73 is configured to analyze signals produced by the metrology tool 71 and outputs a detection signal to the controller 90 according to an analyzing result. For example, the analyzer 73 includes an image analyzer. The analyzer 73 receives the data associated with the images transmitted from the metrology tool 71 and performs an image analysis process on the images of the droplets 82 in the excitation zone. Afterwards, the analyzer 73 sends data related to the analysis to the controller 90. The analysis may include a flow path error or a position error.

In some embodiments, two or more metrology tools 71 are used to monitor different conditions of the light source 120. One is configured to monitor condition of the droplets 82 supplied by the droplet generator 30, and the other is configured to detect energy or intensity of the EUV light radiation 84 produced by the droplet 82 in the light source 120. In some embodiments, the metrology tool 71 is a final focus module (FFM) and positioned in the laser generator 50 to detect light reflected from the droplet 82.

The controller 90 is configured to control one or more elements of the light source 120. In some embodiments, the controller 90 is configured to drive the droplet generator 30 to generate the droplets 82. In addition, the controller 90 is configured to drive the laser generator 50 to fire the laser pulse 51. The generation of the laser pulse 51 may be controlled to be associated with the generation of droplets 82 by the controller 90 so as to make the laser pulse 51 hit each droplet 82 in sequence. The controller 90 may be configured to control delivery of hydrogen gas and exhaust of spent hydrogen gas by the pumps 66, 68.

In some embodiments, the droplet generator 30 includes a reservoir 31 and a nozzle assembly 32. The reservoir 31 is configured for holding the target material 80. In some embodiments, one gas line 41 is connected to the reservoir 31 for introducing pumping gas, such as argon, from a gas source 40 into the reservoir 31. By controlling the gas flow in the gas line 41, the pressure in the reservoir 31 can be manipulated. For example, when gas is continuously supplied into the reservoir 31 via the gas line 41, the pressure in the reservoir 31 increases. As a result, the target material 80 in the reservoir 31 can be forced out of the reservoir 31 in the form of droplets 82. The reservoir 31 receives the target material 80, e.g., liquid tin, from a target supply system that may include one or more low-pressure reservoirs and one or more high-pressure reservoirs.

FIG. 2 is a diagrammatic view of a system 20 that uses spent hydrogen gas of the lithography exposure system 10 to generate electric power in accordance with various embodiments.

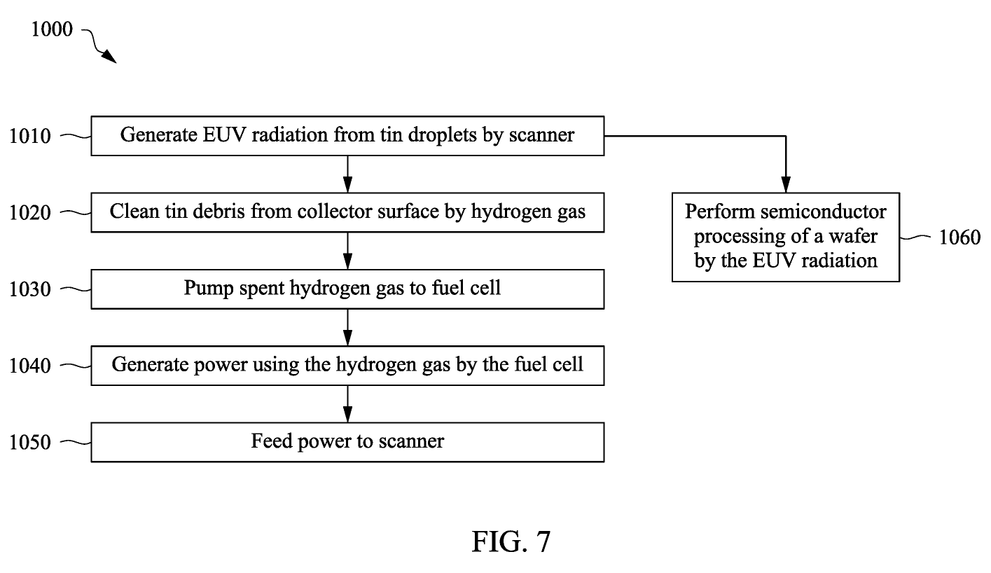

FIG. 7 depicts a flowchart of a process 1000 in accordance with various embodiments. In some embodiments, the process 1000 for forming a device includes a number of acts (1010, 1020, 1030, 1040, 1050 and 1060). The process 1000 will be further described according to one or more embodiments. It should be noted that the operations of the process 1000 may be rearranged or otherwise modified within the scope of the various aspects. It should further be noted that additional processes may be provided before, during, and after the process 1000, and that some other processes may be only briefly described herein. In some embodiments, the process 1000 is performed by the system 20 described in FIGS. 2-6. The embodiments are described with reference to the structural elements described in FIGS. 1A-6, but the process 1000 may be performed by a system having one or more structural elements that are different from those of the system 20.

In FIG. 2, the system 20 includes a facility system 220, the lithography exposure system 10, the pump(s) 66, 68, a fuel cell 200 and a scrubber 210. Operation of the system 20 is described with reference to acts 1010-1060 of the process 1000 depicted in FIG. 7.

The facility system 220 may include various apparatuses and/or sub-systems that facilitate fabrication of semiconductor wafers and/or integrated circuit (IC) dies. To support an EUV scanner (e.g., the lithography exposure system 10), which projects EUV light onto the semiconductor wafer to pattern very small features, the facility system may include one or more of a cleanroom, a wafer handling and/or automation system, mask equipment, metrology and inspection tools, vacuum systems, resist material and handling systems, gas and chemical deliver systems, cooling and/or chilling systems, power supply systems, water purification systems and waste treatment systems. The cleanroom maintains contamination control. Cleanrooms have controlled temperature, humidity and particle levels that are beneficial to achieving improved quality and reliability of semiconductor manufacturing. The wafer handling and/or automation system may include robotic systems for wafer handling, which are beneficial to move wafers between different tools and processing stations within the fab. Automated wafer carriers and transport systems, such as overhead transport (OHT) reduce human contact to prevent contamination. Mask equipment is operated for producing EUV masks, which are used to pattern the semiconductor wafers. The mask equipment may include mask-making equipment, inspection tools and repair systems. The metrology and inspection tools are beneficial to measure and verify feature dimensions and measure quality of the fabricated semiconductor devices. The vacuum system may provide a vacuum environment that is beneficial for EUV lithography, such as efficiency. Resist material handling and processing systems may include handling and processing equipment that are beneficial for photosensitive resist materials, which are sensitive to EUV light and benefit from precise control during coating, baking, and development steps. The gas and chemical delivery systems deliver gases and chemicals to the different tools and processes. The cooling and chilling systems cool and/or chill many tools in the semiconductor fab that generate heat during operation and benefit from maintaining stable operating temperatures. Other systems of the facilities system can include the power supply system 222, water purification system, gas supply system and waste treatment system.

In FIG. 2, the lithography exposure system 10 may generate EUV light radiation 84 from tin droplets 82, corresponding to act 1010 of FIG. 7. The EUV light radiation 84 may be used to perform semiconductor processing of a wafer, corresponding to act 1060 of FIG. 7. During the generation of the EUV light radiation 84, the tin droplets 82 are struck by laser light, which may form debris 82A that accumulates on a surface of the collector 60.

The debris 82A may be cleaned by directing hydrogen gas toward the surface of the collector 60, corresponding to act 1020 of FIG. 7. The hydrogen gas is delivered or supplied to the lithography exposure system 10 from the facility system 220 via one or more transport lines 230 that connect the facility system 220 to the lithography exposure system 10. For example, the facility system 220 may include a hydrogen gas supply system that includes one or more tanks that hold the hydrogen gas and one or more pumps that pump the hydrogen gas toward the lithography exposure system 10 via the transport line(s) 230.

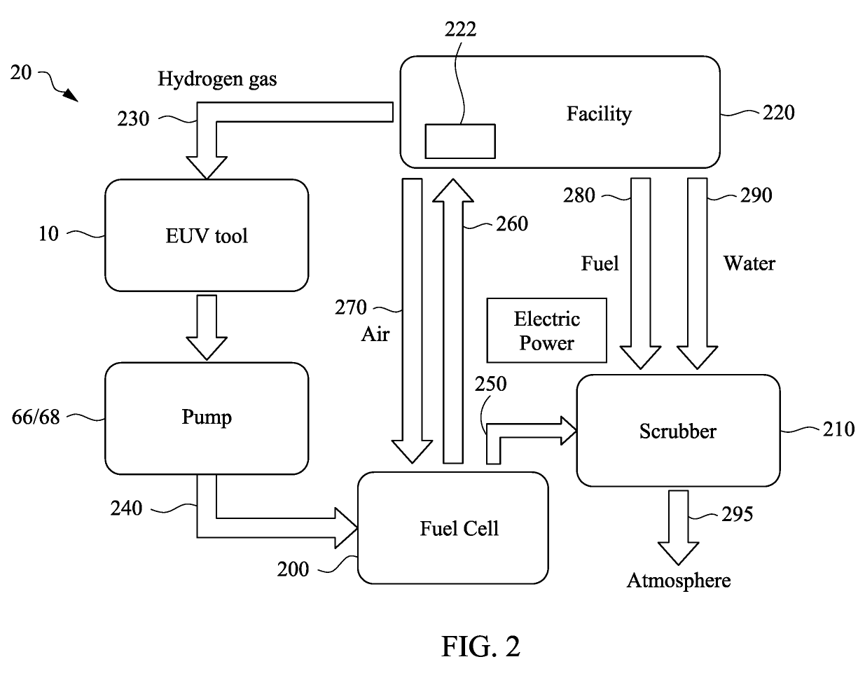

As hydrogen gas is expelled into the lithography exposure system 10, one or more pumps 66, 68 draw spent hydrogen gas out of the lithography exposure system 10 and deliver the spent hydrogen gas to the fuel cell 200 via one or more transport lines 240, corresponding to act 1030 of FIG. 7. The transport line(s) are in fluidic communication between the pump(s) 66, 68 and the fuel cell 200. In some embodiments, the fuel cell 200 includes a plurality of fuel cells that are connected together, e.g., in a stack. A fuel cell 300 and fuel cell block 500 that are embodiments of the fuel cell 200 are described in greater detail with reference to FIGS. 3-6.

The fuel cell 200 takes the spent hydrogen gas and air as inputs, and outputs electric power and hydrogen gas as outputs. Namely, the fuel cell 200 generates electric power using the hydrogen gas, which corresponds to act 1040 of FIG. 7. The hydrogen gas is delivered from the lithography exposure system 10 via the pump(s) 66, 68 and the transport line(s) 240 to the fuel cell. The air containing oxygen is delivered to the fuel cell via the facility system 220 and transport line(s) 270. In some embodiments, the air is compressed are delivered from an air compressor of the facility system 220. The electric power is delivered to the facility system 220 via one or more power lines 260. In some embodiments, the facility system 220 is a load of the fuel cell 200. In some embodiments, the electric power is delivered to an energy storage apparatus of the facility system 220, such as a battery. In some embodiments, the electric power is delivered to a power supply system 222 of the facility system 220.

The power supply system 222 of the facility system 220 may perform various operations to integrate the electric power into the system 20, for example, for use by the lithography exposure system 10. When the electric power is generated, it is beneficial to connect the electric power seamlessly to the facility system’s electrical distribution system. This integration may involve configuring the fuel cell 200 to interface with the power supply system 222 of the facility system 220 and a load distribution system of the facility system 220. It is beneficial for the generated power to flow smoothly and safely into a power network of the facility system 220 without causing disturbances or overloading. The electric power generated by the fuel cell 200 is generally synchronized with power from a main electrical grid. This synchronization includes frequency, voltage and phase of the electric power matching precisely with power parameters of the main electrical grid. Control systems and algorithms may be used to synchronize the two power sources to work harmoniously together, preventing phase mismatches or frequency deviations that could lead to disruptions or damage to sensitive equipment. After the electric power from the fuel cell 200 is integrated into the power system and synchronized with the main electrical grid, power distribution may be managed beneficially. Power electronics devices, such as inverters and converters, can efficiently control flow of the electric power. The power distribution may be adjusted dynamically to direct the electric power to equipment of the system 20, improving energy utilization and avoiding overloads in various areas. Advanced power management algorithms and control systems may be used to generate a stable and reliable power supply throughout the system 20.

The electric power integrated into the power supply system 222 of the facility system 220 is fed to the lithography exposure system 10, corresponding to act 1050 of FIG. 7. By directing the spent hydrogen gas through the fuel cell 200 prior to burning up the spent hydrogen gas in the scrubber 210, the electric power may be generated that is fed back into the power supply system 222 of the facility system 220, which can reduce energy consumed per wafer by the lithography exposure system 10.

The scrubber 210 may be a combustion-wash or “burner washer” scrubber. The scrubber 210 receives fuel and water from the facility system 220 via a transport line 280 and a transport line 290, respectively. The fuel may be used for the burner portion of scrubbing and the water may be used for the washer portion of scrubbing. Namely, the scrubber 210 receives excess hydrogen gas from the fuel cell 200 via a transport line 250. The hydrogen gas may be expelled into a chamber of the scrubber 210 that is heated by burning the fuel, or may be burned directly onto a flame of the scrubber 210 that is formed by burning the fuel. The hydrogen gas and any contaminants therein combust either directly by the flame or indirectly by heat in the chamber, and the broken-down contaminants are washed in the scrubber 210 using the water. Clean exhaust is then released to the atmosphere by a transport line or vent 295. By using the fuel cell 200 to use some or all of the hydrogen gas for generating electrical power, the amount of hydrogen gas burnt up (or wasted) in the scrubber 210 may be reduced, which can reduce overall energy consumption for fabricating the IC dies by the lithography exposure system 10, which may reduce fossil fuel consumption due to reduced loading on the main electrical grid.

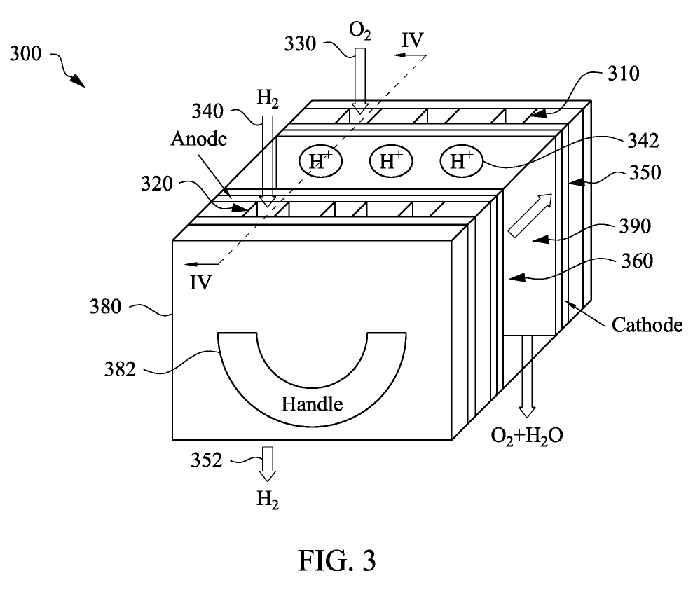

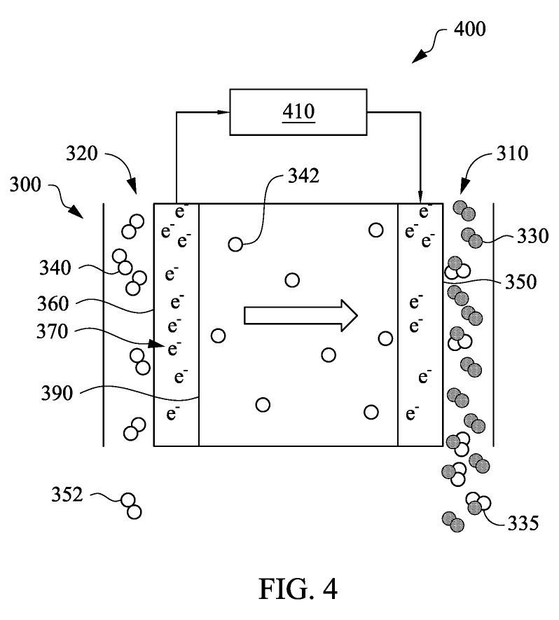

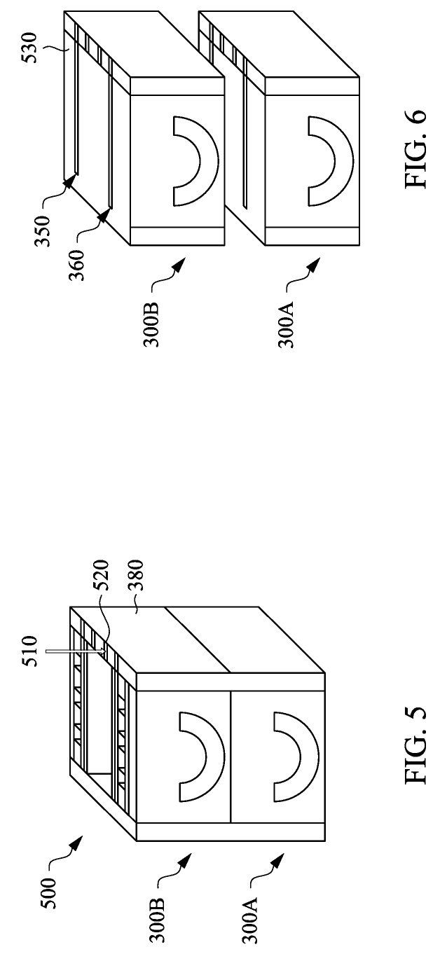

FIGS. 3-7 are diagrammatic perspective and schematic views of a fuel cell 300 and a fuel cell block 500 in accordance with various embodiments. FIG. 3 is a perspective view of the fuel cell 300. FIG. 4 is a schematic view based on a cross-sectional line IV-IV of FIG. 3. FIG. 5 is a perspective view of the fuel cell block 500 in a connected configuration. FIG. 6 is another perspective view of the fuel cell block 500 depicting covers of individual fuel cells.

In FIG. 3 and 4, the fuel cell 300 includes a housing 380, a positive or anode electrode 360, a negative or cathode electrode 350, a membrane 390, a first plate 320 and a second plate 310. The anode electrode 360, cathode electrode 350, membrane 390, first plate 320 and second plate 310 are positioned in the housing 380. The housing 380 may have a handle 382 mounted thereon. Side walls of the housing 380 are omitted from view in FIG. 3 so as not to obstruct view of internal structure of the fuel cell 300.

The first plate 320 may be a first bipolar plate or flow field plate and may be operable to distribute a first reactant gas (e.g., hydrogen) to an electrochemically active area of the fuel cell 300. The first plate 320 may be a conduit for gases within the fuel cell 300. The first plate 320 is adjacent the anode electrode 360. The first plate 320 may include one or more channels or grooves on both sides thereof. The channels provide for gas distribution, namely such that hydrogen gas can flow to reach electrochemical reaction sites at the anode electrode 360. The channels are beneficial to distribute the hydrogen gas evenly across an active surface of an adjacent membrane electrode assembly (MEA) that includes the anode and cathode electrodes 360, 350 and a membrane 390 therebetween. The first plate 320 may also be beneficial to provide connectivity between adjacent fuel cells 300 in a stack (see, for example, fuel cell block 500 of FIG. 5), such that excess hydrogen gas 352 may travel into a subsequent fuel cell beneath the fuel cell 300. A gas-tight seal may be formed between the fuel cells 300, which allows reactant gases (e.g., hydrogen) to flow efficiently between the individual fuel cells 300.

The second plate 310 is similar in most respects to the first plate 320, but is instead located adjacent the cathode electrode 350. The second plate 310 conducts and distributes air that contains oxygen therethrough.

The anode electrode 360 is between the channels of the first plate 320 and the membrane 390. The hydrogen gas 340 may enter the channels of the first plate 320 and then be split into a proton 342 and an electron 370 by the anode electrode 360. In some embodiments, the anode electrode 360 includes platinum or palladium, which is beneficial for splitting hydrogen molecules into protons 342 and electrons 370.

The membrane 390 may be a polymer electrolyte membrane or proton exchange membrane “PEM,” which includes an ion-conducting polymer that permits the protons 342 to pass through while blocking the electrons 370. The membrane 390 may be or include perfluorosulfonic acid (PFSA), polybenzimidazole (PBI), sulfonated polyether ketone (SPEK), sulfonated polyether ether ketone (SPEEK), or the like. A combination of the first plate 320, the membrane 390 and the second plate 310 may be referred to as a membrane electrode assembly or “MEA.”

In some embodiments, the MEA includes additional layers, such as gas diffusion layers or “GDLs.” Each GDL may be or include carbon or carbon-based materials with hydrophobic properties beneficial for efficient gas transport while preventing flooding of the anode and cathode electrodes 360, 350. An overall structure of the MEA including the GDLs may be a stack having sequence as follows (from anode to cathode): anode GDL, anode electrode 360, PEM 390, cathode electrode 350, cathode GDL. On both sides of the MEA, the GDLs may be in direct contact with respective bipolar plates (e.g., the first and second plates 320, 310). The GDLs serve as an interface between the anode and cathode electrodes 360, 350 of the MEA and the bipolar plates, and may provide electrical contact and uniform distribution of the reactant gases (hydrogen and oxygen) to the anode and cathode electrodes 360, 350. The GDLs may also allow byproducts of the electrochemical reactions, such as water vapor, to escape the fuel cell 300.

The cathode electrode 350 of the fuel cell 300 is similar in most respects to the anode electrode 360 in material composition. The cathode electrode 350 is between the membrane 390 and the second plate 310.

As depicted in a fuel cell system 400 of FIG. 4, the cathode electrode 350 and the anode electrode 360 are connected to either end of a load 410. The load 410 may be the power supply system 222 of the facility system 220. In some embodiments, the load 410 is a battery that is charged by electrical current (or electric power) generated by the fuel cell 300.

When the protons 342 leave the anode electrode 360 and enter the membrane 390, a potential difference is created between the anode electrode 360 and the cathode electrode 350, such that the electrons 370 flow from the anode electrode 360, to the load 410, and then to the cathode electrode 350.

When the protons 342 passing through the membrane 390 reach the cathode electrode 350, the protons 342 may recombine with the electrons 370 in the cathode electrode 350 to form hydrogen atoms. Then, the hydrogen atoms form water 335 with oxygen in the air that flows through the second plate 310. The water 335 and excess oxygen 330 are expelled from the fuel cell 300.

FIGS. 5 and 6 are diagrammatic perspective views of a fuel cell block 500 in accordance with various embodiments. The fuel cell block 500 includes at least two fuel cells 300A, 300B that are arranged in a vertical stack. The fuel cells 300A, 300B are similar in most respects to the fuel cells 200, 300 described with reference to FIGS. 2-4. The housing 380 may include side walls in which conduits 520 are formed. Water 510 may be passed through the conduits 520 to cool the fuel cells 300A, 300B. The conduits 520 of the fuel cells 300A, 300B are aligned so that the water 510 can pass from one fuel cell 300B to the next fuel cell 300A. The anode electrodes 360 and the cathode electrodes 350 of the respective fuel cells 300A, 300B are aligned and may be in direct contact with each other. As such, the fuel cell block 500 may have high current driving capacity than a single fuel cell 300 has on its own. The fuel cell block 500 may include many more than the two fuel cells 300A, 300B depicted in FIG. 5.

In FIG. 6, in the event that one or more of the fuel cells 300A, 300B of the fuel cell block 500 is in a condition for removal, such as when maintenance or repair is beneficial, the fuel cell 300A and/or the fuel cell 300B may be removed easily and replaced with a replacement fuel cell so that operation may continue uninterrupted. This ease of removal and replacement is also a benefit provided by having the conduits 520 and the electrodes 360, 350 aligned among the fuel cells 300A, 300B of the stack.

In some embodiments, each of the fuel cells 300A, 300B includes a cover 530. The cover 530 may be reversible, which is beneficial to performing safe, quick and easy removal and replacement of a fuel cell 300A, 300B that is broken or ready for maintenance. The structure of reversible cover 530 is connected to the housing 380 mechanically with bolts, nuts or the like and is able to be opened for internal maintenance. The electrodes 360, 350, which protrude from the reversible cover 530, can be accessed to confirm whether the fuel cells 300A, 300B are connected to each other properly to transmit electrical current to generate power.

Embodiments may provide advantages. The fuel cell 200, 300 and/or fuel cell block 500 positioned between the lithography exposure system 10 and the scrubber 210 uses exhausted hydrogen gas from the lithography exposure system 10 to generate electric power that can be used to reduce energy consumed per wafer by the lithography exposure system 10. The fuel cell block 500 including two or more fuel cells 300A, 300B in a stack has benefits of quick and easy repair and maintenance, which reduces downtime of the fuel cell block 500.

In accordance with at least one embodiment, a method includes: forming a mask layer on a semiconductor wafer; generating light by a tin droplet by a lithography exposure system; exposing the mask layer by the light; cleaning tin debris accumulated in the lithography exposure system by hydrogen gas; pumping the hydrogen gas from the lithography exposure system to a fuel cell; and generating electric power by the fuel cell.

In accordance with at least one embodiment, a method includes: processing a semiconductor wafer by an extreme ultraviolet (EUV) scanner; cleaning the EUV scanner by hydrogen gas; generating electric power by passing the hydrogen gas through a fuel cell; and feeding the electric power back to the EUV scanner.

In accordance with at least one embodiment, a system includes: an extreme ultraviolet (EUV) scanner operable to generate EUV light by striking tin droplets with at least one laser pulse; a cleaning system in the EUV scanner operable to direct hydrogen gas that cleans the EUV scanner; a pump that is operable to remove the hydrogen gas from the EUV scanner; a fuel cell that, in operation: receives the hydrogen gas from the pump; generates electric power by the hydrogen gas; and forms water from a first portion of the hydrogen gas; a scrubber that, in operation, burns a second portion of the hydrogen gas; and a power supply system that, in operation: receives the electric power from the fuel cell; and delivers the electric power to the EUV scanner.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
generating light by a lithography exposure system;
cleaning the lithography exposure system by hydrogen gas;
pumping the hydrogen gas from the lithography exposure system to a fuel cell;
generating electric power by the fuel cell; and
feeding the electric power to the lithography exposure system.

2. The method of claim 1, further comprising:
burning the hydrogen gas leaving the fuel cell by a scrubber.

3. The method of claim 2, wherein the burning the hydrogen gas includes burning less of the hydrogen gas by the scrubber than was pumped from the lithography exposure system.

4. The method of claim 1, wherein the generating electric power by the fuel cell includes generating the electric power by a fuel cell block including the fuel cell and at least one additional fuel cell in contact with the fuel cell.

5. The method of claim 4, further comprising cooling the fuel cell block by water.

6. The method of claim 5, wherein the cooling includes passing the water through conduits in respective housings of the fuel cell and the at least one additional fuel cell.

7. The method of claim 1, wherein the feeding the electric power includes integrating the electric power with a main power supply by a power supply system and delivering the electric power to the lithography exposure system by the power supply system.

8. The method of claim 1, further comprising:
charging a battery by the electric power.

9. A method, comprising:
cleaning an extreme ultraviolet (EUV) scanner by hydrogen gas;
generating electric power by passing the hydrogen gas through a fuel cell; and
feeding the electric power back to the EUV scanner.

10. The method of claim 9, wherein the generating electric power includes passing the hydrogen gas through a fuel cell block including a plurality of fuel cells that includes the fuel cell.

11. The method of claim 10, further comprising replacing one of the plurality of fuel cells.

12. The method of claim 10, further comprising:
forming water from a first portion of the hydrogen gas by the fuel cell block; and
burning a second portion of the hydrogen gas by a scrubber.

13. The method of claim 10, further comprising water cooling the fuel cell block via respective pluralities of conduits in a housing of each of the plurality of fuel cells.

14. The method of claim 13, wherein the feeding the electric power includes:
integrating the electric power with a main power supply by a power supply system; and
delivering second electric power including at least a portion of the electric power to the EUV scanner by the power supply system.

15. A system comprising:
an extreme ultraviolet (EUV) scanner operable to generate EUV light;
a cleaning system in the EUV scanner operable to direct hydrogen gas that cleans the EUV scanner;
a pump operable to remove the hydrogen gas from the EUV scanner;
a fuel cell that, in operation, receives the hydrogen gas from the pump and generates electric power by the hydrogen gas;
a power supply system that, in operation, receives the electric power from the fuel cell and delivers the electric power to the EUV scanner.

16. The system of claim 15, further comprising a fuel cell block that includes the fuel cell and a second fuel cell in direct contact with the fuel cell.

17. The system of claim 16, wherein:
the fuel cell includes a first housing having first conduits passing therethrough; and
the second fuel cell includes a second housing having second conduits passing therethrough, the second conduits being aligned with the first conduits.

18. The system of claim 17, wherein each of the first and second fuel cells includes a reversible cover mounted to the respective first and second housing.

19. The system of claim 15, wherein the power supply system includes a battery, and the fuel cell is operable to charge the battery by the electric power.

20. The system of claim 15, further comprising:
a scrubber that, in operation, receives the hydrogen gas from the fuel cell; and
a facility system including the power supply system, the facility system, in operation:
supplying the hydrogen gas to the cleaning system;
supplying air to the fuel cell; and
supplying fuel and water to the scrubber.
